(19) United States
(12) Patent Application Publication
(10) Pub. No.: US 2012/0199948 A1
(43) Pub. Date: Aug. 9, 2012

(54) SEMICONDUCTOR CHIP COMPRISING PROTECTION MEANS AGAINST A PHYSICAL ATTACK

(75) Inventor: Marc SAISSE, Villelaure (FR)

(73) Assignee: INSIDE SECURE, Aix-en-Provence (FR)

(21) Appl. No.: 13/368,753

(22) Filed: Feb. 8, 2012

(30) Foreign Application Priority Data
Feb. 9, 2011 (FR) 11 00401

(51) Int. Cl. H01L 27/06; H01L 21/02

(52) U.S. Cl. 257/532; 438/17; 257/E27.013; 257/E21.008

(57) ABSTRACT

A semiconductor chip includes a semiconductor substrate, an integrated circuit region having an integrated circuit, and conductive lines extending above the integrated circuit region. To protect the semiconductor chip against a physical attack, the semiconductor chip includes an array of protection capacitors extending above the conductive lines, at least first and second interconnection conductive lines, arranged to interconnect the protection capacitors in parallel, and a cprotection circuit configured to prevent at least some data from circulating on at least some conductive lines, when a short occurs in at least one protection capacitor.

### BACKGROUND OF THE INVENTION

Embodiments of the present invention relate to a semiconductor chip including a semiconductor substrate, an integrated circuit region having an integrated circuit, conductive lines extending above the integrated circuit region, and a protection circuit extending above the conductive lines to protect the semiconductor chip against a physical attack.

A semiconductor chip generally includes a semiconductor substrate within which an integrated circuit region is embedded. The integrated circuit region includes active and passive electronic components such as transistors, resistors, capacitors, and the like. Conductive lines are generally provided above the integrated circuit region to interconnect parts of the integrated circuit or to connect the integrated circuit to surface contact pads of the semiconductor chip. These conductive lines carry data which may be “sensitive”, for example a secret cryptographic key, and are therefore subjected to physical attacks. A “physical attack” is defined as an attempt to recover sensitive information directly from the internal circuitry of a semiconductor chip.

More particularly, attackers may try to recover sensitive data by accessing the conductive lines and sensing the electrical signals circulating thereon. To that effect, they may use a Chemical Mechanical Polishing technique to remove one or more dielectric layers until the conductive lines are reached, or a Scanning Electron Microscope or Focused Ion Beam technique to make a hole through a dielectric material to reach the conductive lines.

To prevent such attacks, it is known from U.S. Pat. No. 4,933,898 to arrange a conductive layer above the conductive lines of a semiconductor chip. The conductive layer may provide a voltage supply to the active components. Thus, if the conductive layer is removed, the integrated circuit is no longer powered and ceases to function.

It is also known from U.S. Pat. No. 5,861,662 to provide an anti-tamper shield including a bond wire passing through a protective layer, such as an epoxy encapsulating layer.

Nevertheless, it is possible for an attacker to circumvent these types of countermeasures by applying the power supply voltage to the integrated circuit through another conductive path, or by conducting a local physical attack that does not dramatically alter the conductive layer.

United States Patent Application No. 2010/0090714 also describes an integrated circuit having a circuit to be protected, a protective layer over the circuit to be protected, and a sensing circuit arranged to sense an impedance of the protective layer compared to a reference impedance located on the integrated circuit. In an embodiment, the protective layer includes an array of fringe capacitors.

It may be desired to provide an alternative protection circuit to protect an integrated circuit against both global and local physical attacks.

### BRIEF SUMMARY OF THE INVENTION

Embodiments of the invention relate to a semiconductor chip, including a semiconductor substrate, an integrated circuit region including an integrated circuit, conductive lines extending above the integrated circuit region, and a protection circuit extending above the conductive lines, to protect the semiconductor chip against a physical attack, the protection circuit including at least one array of protection capacitors extending above the conductive lines, each protection capacitor including a lower conductive plate, an upper conductive plate, and a dielectric layer between the lower and upper plates, and at least first and second interconnection conductive lines, arranged to interconnect the protection capacitors in parallel. The integrated circuitry is configured to prevent at least some data from circulating on at least some conductive lines when a short occurs in at least one protection capacitor.

In one embodiment, the protection capacitors are biased by a power supply voltage of the integrated circuit, so that the integrated circuit ceases to function when at least one protection capacitor is short-circuited.

In one embodiment, the semiconductor chip includes circuitry for detecting a short in a protection capacitor and supplying a warning signal to the integrated circuit when a short is detected.

In one embodiment, the semiconductor chip includes circuitry for monitoring the electrical continuity of at least one of the interconnection conductive lines between two points thereof, and supplying a warning signal to the integrated circuit when a continuity default is detected.

In one embodiment, the integrated circuit is configured to perform, in response to a warning signal, at least one of the following protective actions: stopping an operation being carried out, resetting the integrated circuit, erasing all or part of a memory, or self-destructing the integrated circuit or parts thereof.

In one embodiment, the protection capacitors Ci cover more than 90% of the total area occupied by the array of capacitors.

In one embodiment, the combined thickness of the dielectric layer and the upper plate is less than 300 nanometers.

In one embodiment, the semiconductor chip includes a further conductive line arranged above the protection capacitors, and circuitry for monitoring the electrical continuity of the conductive line and supplying a warning signal to the integrated circuit when a continuity default is detected.

Embodiments of the invention also relate to a method for protecting a semiconductor chip against a physical attack, the semiconductor chip including a semiconductor substrate, an integrated circuit region including an integrated circuit, conductive lines extending above the integrated circuit region, the method including: providing at least one array of protection capacitors extending above the conductive lines, each protection capacitor including a lower conductive plate, an upper conductive plate, and a dielectric layer between the lower and upper plates; providing at least first and second interconnection conductive lines, arranged to interconnect the protection capacitors in parallel; and preventing at least some data from circulating on at least some conductive lines when a short occurs in at least one protection capacitor.

In one embodiment, the method includes biasing the protection capacitors by a power supply voltage of the integrated circuit, so that the integrated circuit ceases to function when at least one protection capacitor is short-circuited.

In one embodiment, the method includes detecting a short in a protection capacitor, and supplying a warning signal to the integrated circuit when a short is detected.

In one embodiment, the method includes monitoring the electrical continuity of at least one of the interconnection conductive lines between two points thereof, and supplying a warning signal to the integrated circuit when a continuity default is detected.

In one embodiment, the method includes configuring the integrated circuit so that it performs, in response to a warning signal, at least one of the following protective actions: stopping an operation being carried out, resetting the integrated circuit, erasing all or part of a memory, or self-destructing the integrated circuit or parts thereof.

In one embodiment, the method includes designing the array of capacitor Ci so that it covers more than 90% of the area it occupies.

In one embodiment, the method includes providing a further conductive line arranged above the protection capacitors, and monitoring the electrical continuity of the conductive line and supplying a warning signal to the integrated circuit when a continuity default is detected.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

Embodiments of the present invention will now be described in connection with, but not limited to, the appended drawings in which:

FIG. 1 is a top view of a semiconductor chip according to a first embodiment of the invention;

FIG. 2 is a cross-sectional view of parts of the semiconductor chip;

FIG. 3 is a electrical diagram of a protection circuit integrated within the semiconductor chip;

FIG. 4 is an electrical diagram of an embodiment of an integrated circuit according to the invention; and

FIG. 5 is a top view of a semiconductor chip according to a second embodiment of the invention.

### DETAILED DESCRIPTION OF THE INVENTION

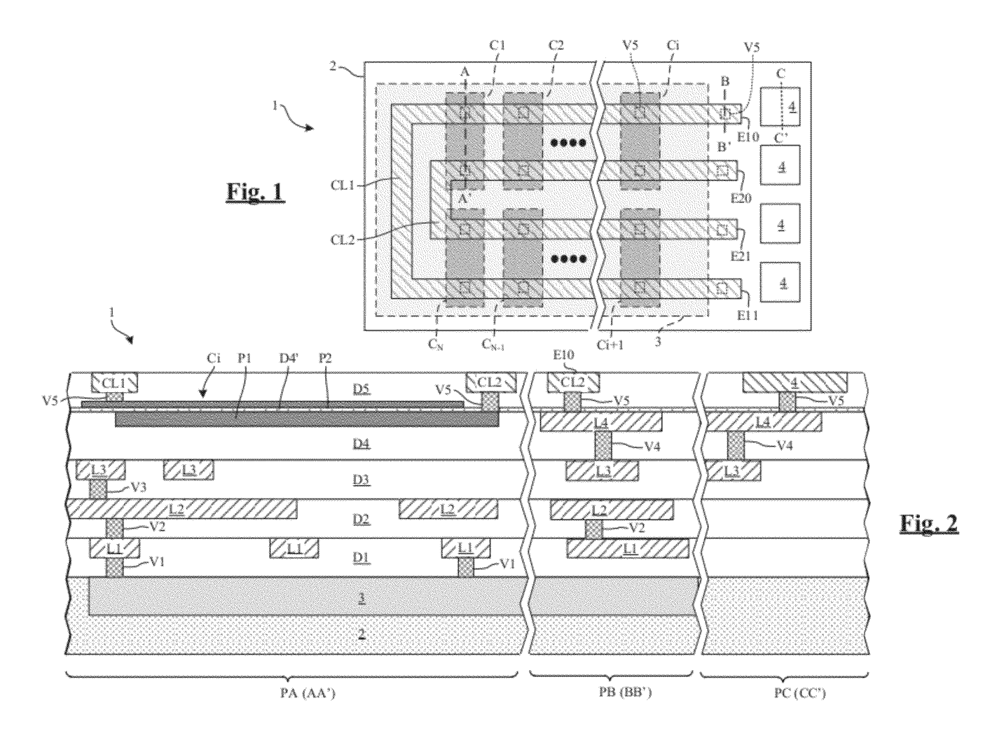

FIG. 1 is a top view of a semiconductor chip 1 according to one embodiment of the invention. The semiconductor chip 1 includes a semiconductor substrate 2, an integrated circuit region 3 embedded within the substrate, and one or more top surface contact pads 4 to receive or supply electrical signals from or to the outside (e.g. power supply voltage, ground potential, data in, data out, etc.).

The semiconductor chip 1 further includes protection circuitry to protect the semiconductor chip against a physical attack. The protection circuitry includes an array of capacitors Ci (C1, C2 . . . C_{N-1}, C_{N}) and two conductive lines CL1, CL2 interconnecting capacitors Ci so that they are arranged in parallel. Each conductive line CL1 and CL2 has two ends, respectively E10, E11 and E20, E21, linked to a protection circuit located in the integrated circuit region 3, which will be described later.

FIG. 2 is a cross-sectional schematic view of different parts PA, PB, and PC of the semiconductor chip 1 along line segments AA′, BB′, and CC′ shown in FIG. 1. It is to be noted that the different elements shown in FIG. 2 may not be to scale for illustrative clarity, in particular as far as their thicknesses are concerned. Part PA schematically shows the cross-sectional structure of the semiconductor chip in a region including the protection capacitor C1. It is assumed here that all protection capacitors Ci have a similar structure. Part PB schematically shows the cross-sectional structure of the semiconductor chip in a region including the end E10 of conductive line CL1. Part PC schematically shows the cross-sectional structure of the semiconductor chip in a region including one surface contact pad 4.

Referring to FIG. 2, part PA, the semiconductor chip includes, above the integrated circuit region 3, conductive lines Lj interconnecting parts of the integrated circuit region 3 or connecting the integrated circuit region to the surface contact pads 4.

In this example embodiment, the semiconductor chip includes first conductive lines L1 extending above the integrated circuit region 3 and embedded in a first dielectric layer D1; second conductive lines L2 extending above the first conductive lines L1 and embedded in a second dielectric layer D2; third conductive lines L3 extending above the second conductive lines L2 and embedded in a third dielectric layer D3; and fourth conductive lines L4 extending above the second conductive lines L3 and embedded in a third dielectric layer D4. Conductive lines L1 are connected to the integrated circuit region 3 through conductive vias V1 passing through the dielectric layer D1 and/or are connected to conductive line L2 through conductive vias V2 passing through the dielectric layer D2. Likewise, conductive lines L3 are connected to conductive lines L2 through conductive vias V3 passing through the dielectric layer D3 and/or are connected to conductive line L4 through conductive vias V4 passing through the dielectric layer D4. Referring to conventional microelectronics processes, conductive lines L1, L2, L3, L4 correspond for example to metal 1, metal 2, metal 3, and metal 4 layers (aluminum or copper) deposited on the semiconductor chip and then etched during the manufacturing thereof. Alternately, conductive lines L1, L2, L3, L4 may be formed using a damascene deposition process.

The protection capacitor Ci includes a lower conductive plate P1 and an upper conductive plate P2. Plate P1 extends above conductive lines L3 and is embedded in the dielectric layer D4. Plate P2 extends above plate P1 and is embedded in a dielectric layer D5 extending over dielectric layer D4. Plates P1 and P2 are separated by a thin layer of dielectric material D4′, which may be the same dielectric material as that of layer D4 or D5, for example SiO2.

In one embodiment, plates P1 and P2 are made during the manufacturing of the metal 4 layer. Plate P1 is formed together with conductive lines L4. The dielectric layer D4′ is then deposited over the semiconductor chip and removed where is it not desired. Then plate P2 is formed above plate P1. In total, the formation of plate P2 and dielectric layer D4′ necessitates two additional manufacturing steps compared to a conventional manufacturing process.

In one embodiment, plate P2 and the dielectric layer D4′ are each thinner than plate P1, so that the upper part of capacitor is as fragile as possible while being capable to support a determined voltage.

In one embodiment, the combined thickness of plate P2 and dielectric layer D4′ is less than 300 nm (nanometers). In one embodiment, the thickness of plate P1 is on the order of 500 nm, the thickness of plate P2 is on the order of 250 nm, and the thickness of the dielectric D4′ is on the order of 35 nm.

In one embodiment, the surface of the protection capacitors Ci and the spacing between capacitors Ci are chosen such that the capacitors Ci cover more than 90% of the total area occupied by the array of capacitors. For example, the spacing may be 0.5 micrometers and the capacitors surface may be 30*30 micrometers, so that the capacitors Ci covers 96% (100*((30*30)/(30.5*30.5))) of the total area covered by the array of capacitors Ci.

The conductive lines CL1, CL2 extend above the upper plate P2 and are deposited on or embedded within the dielectric layer D5. They are connected to plates P1, P2, respectively, through conductive vias V5 passing through the dielectric layer D5. Referring again to conventional microelectronics processes, conductive lines CL1, CL2 are for example made from a metal 5 layer that is deposited on the semiconductor chip substrate then etched during the manufacturing thereof, or are formed using a damascene deposition process.

Referring to FIG. 2, part PB, the ends E10, E11, E20, E21 of conductive lines CL1, CL2 are linked to the protection circuit located in the integrated circuit region 3 through conductive vias V5 passing through the dielectric D5, and through conductive lines L4, L3, L2, L1 and conductive vias V4, V3, V2, V1 (not shown).

Referring to FIG. 2, part PC, the top surface contact pads 4 are also linked to the integrated circuit region 3 through conductive vias V5 passing through the dielectric D5, and through conductive lines L4, L3, L2, L1 and conductive vias V4, V3, V2, V1 (not shown).

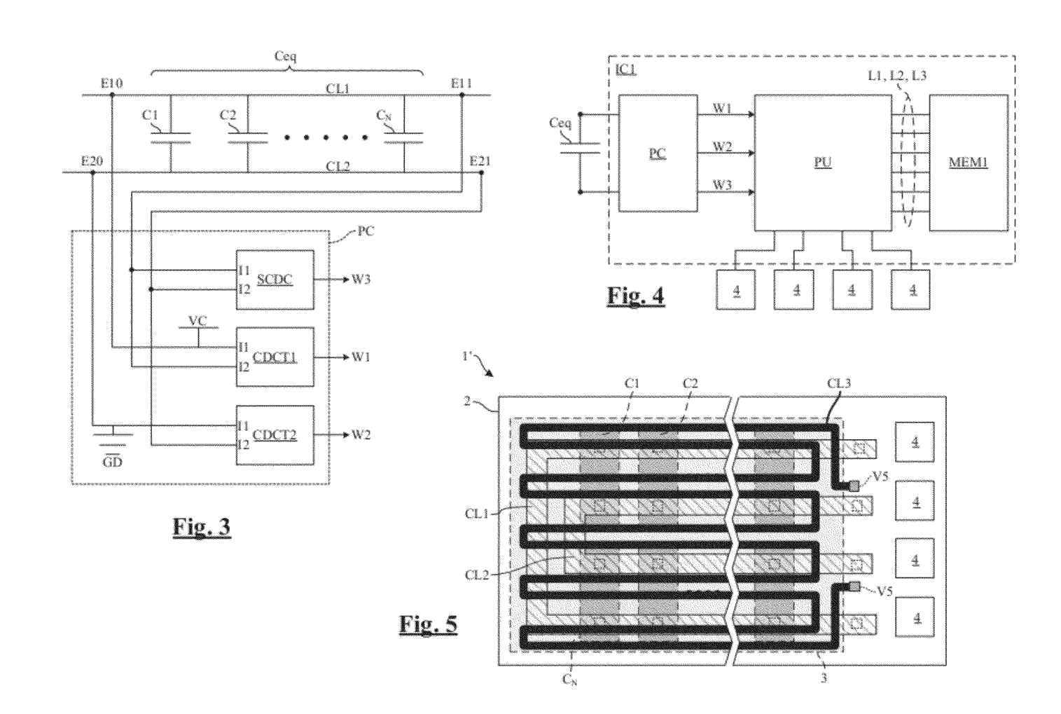

FIG. 3 is an electrical diagram of an embodiment of the above-mentioned protection circuit. The protection circuit PC includes a first continuity detection circuit CDCT1, a second continuity detection circuit CDCT2, and a short circuit detection circuit SCDC.

The continuity detection circuit CDCT1 includes a first input I1 linked to the end E10 of conductive line CL1 and a second input 12 linked to the end E11 of conductive line CL1. Input I1 also receives a control voltage VC, for example the power supply voltage of the integrated circuit.

The continuity detection circuit CDCT2 includes a first input I1 linked to the end E20 of conductive line CL2 and a second input 12 linked to the end E21 of conductive line CL2. Input I1 also receives a reference voltage GD, for example the ground potential of the integrated circuit.

The continuity detection circuit CDCT1 supplies a control signal W1 which has a normal value, for example 1 (i.e., VC), when both inputs I1 and I2 receive the voltage VC, and which has a warning value, for example 0 (i.e., ground potential), when at least one input I1 or I2 does not receive the voltage VC, which means that there is no longer electrical continuity between the two ends of line CL1 or that voltage VC is no longer applied to input I1.

Likewise, the continuity detection circuit CDCT2 supplies a control signal W2 which has a normal value, for example 1, when both inputs I1 and I2 are at the same reference potential GD, and which has a warning value, for example 0, when at least one input I1 or I2 is not connected to the reference potential, which means that there is no longer electrical continuity between the two ends of line CL2 or that the reference potential is no longer applied to input I1.

Thus, if an attacker tries to remove the upper layers of the semiconductor chip to access conductive lines L1, L2, L3 and monitor the electrical signals circulating thereon, the continuity of at least one line CL1, CL2 will be altered and the fault detected by the corresponding continuity detection circuit.

The short detection circuit SDCT includes a first input I1 linked to the end E11 of conductive line CL1 and a second input I2 linked to the end E21 of conductive line CL2. In an embodiment, a second short detection circuit having inputs linked to the ends E10, E20 of conductive lines CL1, CL2 may also be provided.

The short detection circuit SDCT supplies a control signal W3 which has a normal value, for example 1, when input I1 receives the voltage VC and input 12 receives the reference potential, and which has a warning value, for example 0, when at least one input I1 or I2 does not receive the voltage VC or the reference potential.

It is to be noted that as the protection capacitors Ci are connected in parallel, they form an equivalent capacitor Ceq whose value is equal to the sum of the individual values of the capacitors Ci (C1−C_{N}). If an attacker tries to make a hole in the dielectric material layers down to the conductive lines L1, L2, L3, for example using a Focused Ion Beam technique, the plate P1, P2 of at least one protection capacitor Ci will most likely be short-circuited. In that case, the equivalent capacitor Ceq will also be short-circuited. Inputs I1, I2 will receive voltage VC, or at least input I1 will receive a voltage different than VC (partial short with a series resistance not equal to zero), so that the warning signal W3 will go to 0.

In another embodiment, at least one of the detection circuits CDCT1, CDCT2, SDCT may be provided.

The integrated circuit implemented in the integrated circuit region 3 is configured to perform a protective action when at least one of the control signals W1, W2, W3 has the warning value. The protective action may be any known protective action, such as:
stopping an operation being carried out, and/or
resetting the integrated circuit, and/or
erasing all or part of a memory containing sensitive data, and/or
self-destructing the integrated circuit or parts thereof, for example by blowing fuses,

and the like, depending on the type of integrated circuit and the degree of protection sought.

In the case where the control voltage VC is the supply voltage of the integrated circuit, a short in one protection capacitor Ci will also power down the integrated circuit.

FIG. 4 is an electrical diagram of an example embodiment of an integrated circuit IC1 implemented in the integrated circuit region 3. The integrated circuit IC1 includes a processing unit PU, a memory MEM1, and the protection circuit PC. The processing unit PU is linked to surface contact pads 4 in order to receive or emit electrical signals. It is also linked to memory MEM1 via an address and data bus including certain of the above-described conductive lines L1, L2, L3. The protection circuit PC supplies the warning signals W1, W2, W3 to the processing unit PU, which is therefore able to sense an attack. In case of such an attack, the processing unit PU performs a defensive action, such as one of those described above. In this manner, the address and data bus between processing unit PU and memory MEM1 is protected.

In an embodiment, the integrated circuit IC1 may be a contactless integrated circuit, such as a tag, using inductive coupling and load modulation techniques or electrical coupling and backscattering techniques to receive and emit data. In such an embodiment, surface contact pads 4 are connected to an RF antenna coil or to a UHF antenna. The power supply voltage of the integrated circuit is extracted by induction from the magnetic or electrical field surrounding the semiconductor chip, through the RF antenna coil or the UHF antenna. Thus, assuming that such power supply voltage is applied to the protection capacitors Ci, if an attacker causes a short-circuit in one protection capacitor Ci, the equivalent capacitor Ceq will also be short-circuited and the integrated circuit will cease to function as it no longer receives a voltage supply.

Protection capacitors Ci according to the invention may be arranged over the entire area of the integrated circuit region or merely over some areas containing sensitive circuitry or conductive lines carrying sensitive data, for example a cryptographic co-processor, its associated RAM memory, or a data bus linking these elements together.

FIG. 5 is a top view of a semiconductor chip 1′ according to another embodiment of the invention. The semiconductor chip 1′ is identical to the previously described semiconductor chip 1 except in that it further includes a conductive line CL3 arranged in a loop, preferably according to a serpentine pattern so as to cover a large area. The conductive line CL3 extends above the integrated circuit region 3. It may be arranged above or below the conductive lines CL1, CL2, or in the same plane as that of conductive lines CL1, CL2 with insulating bridges so as to not be in contact with these lines at crossing points.

The conductive line CL3 carries a monitoring signal and is connected on both ends to the above-described protection circuit through conductive vias V5 and buried conductive lines L4, L3, L2, L1. In the protection circuit, a third continuity detection circuit (not shown in FIG. 3) is provided to monitor the continuity of line CL3 according to the above-described principle.

It will be apparent to the skilled person that different other embodiments of the present invention may be provided. In particular, the surface protection capacitors Ci may be arranged at the extreme top surface of the semiconductor chip instead of being integrated at a level corresponding to the next-to-last conductive level (metal 4 in the example shown in FIG. 2). In that case, the interconnection conductive lines CL1, CL2 may be buried and extend under the protection capacitors Ci instead of extending over the protection capacitors Ci. In other embodiments, a semiconductor chip according to the invention may include different groups of interconnected protection capacitors Ci independent of each other and linked to the same protection circuit or to separate protection circuits.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I/We claim:

1. A semiconductor chip comprising:
a semiconductor substrate
an integrated circuit region comprising an integrated circuit,
conductive lines extending above the integrated circuit region, and
a protection circuit extending above the conductive lines to protect the semiconductor chip against a physical attack, the protection circuit comprising:
at least one array of protection capacitors extending above the conductive lines, each protection capacitor comprising a lower conductive plate, an upper conductive plate, and a dielectric layer between the lower and upper plates, and
at least first and second interconnection conductive lines, arranged to interconnect the protection capacitors in parallel,
the integrated circuit being configured to prevent at least some data from circulating on at least some conductive lines when a short occurs in at least one protection capacitor.

2. The semiconductor chip according to claim 1, wherein the protection capacitors are biased by a power supply voltage of the integrated circuit, so that the integrated circuit ceases to function when at least one protection capacitor is short-circuited.

3. The semiconductor chip according to claim 1, further comprising a circuit configured to detect a short in a protection capacitor and supply a warning signal to the integrated circuit when a short is detected.

4. The semiconductor chip according to claim 3, wherein the integrated circuit is configured to perform, in response to a warning signal, at least one of the following protective actions:
(i) stopping an operation being carried out,
(ii) resetting the integrated circuit,
(iii) erasing all or part of a memory,
(iv) self-destructing the integrated circuit or parts thereof.

5. The semiconductor chip according to claim 1, further comprising a circuit configured to monitor the electrical continuity of at least one of the interconnection conductive lines between two points thereof, and supply a warning signal to the integrated circuit when a continuity default is detected.

6. The semiconductor chip according to claim 5, wherein the integrated circuit is configured to perform, in response to a warning signal, at least one of the following protective actions:
(i) stopping an operation being carried out,
(ii) resetting the integrated circuit,
(iii) erasing all or part of a memory,
(iv) self-destructing the integrated circuit or parts thereof.

7. The semiconductor chip according to claim 1, wherein the protection capacitors cover more than 90% of a total area occupied by the array of capacitors.

8. The semiconductor chip according to claim 1, wherein the combined thickness of the dielectric layer and the upper plate is less than 300 nanometers.

9. The semiconductor chip according to claim 1, further comprising a third interconnection conductive line arranged above the protection capacitors, and a monitoring circuit configured to monitor the electrical continuity of the third interconnection conductive line and supply a warning signal to the integrated circuit when a continuity default is detected.

10. A method for protecting a semiconductor chip against a physical attack, the semiconductor chip comprising a semiconductor substrate, an integrated circuit region comprising an integrated circuit, and conductive lines extending above the integrated circuit region, the method comprising:
providing at least one array of protection capacitors extending above the conductive lines, each protection capacitor comprising a lower conductive plate, an upper conductive plate, and a dielectric layer between the lower and upper plates,
providing at least first and second interconnection conductive lines, arranged to interconnect the protection capacitors in parallel, and
preventing at least some data from circulating on at least some conductive lines when a short occurs in at least one protection capacitor.

11. The method according to claim 10, further comprising biasing the protection capacitors by a power supply voltage of the integrated circuit, so that the integrated circuit ceases to function when at least one protection capacitor is short-circuited.

12. The method according to claim 10, further comprising:
detecting a short in a protection capacitor, and
supplying a warning signal to the integrated circuit when a short is detected.

13. The method according to claim 12, further comprising configuring the integrated circuit to perform, in response to a warning signal, at least one of the following protective actions:
(i) stopping an operation being carried out,
(ii) resetting the integrated circuit,
(iii) erasing all or part of a memory,
(iv) self-destructing the integrated circuit or parts thereof.

14. The method according to claim 10, further comprising:
monitoring the electrical continuity of at least one of the interconnection conductive lines between two points thereof, and
supplying a warning signal to the integrated circuit when a continuity default is detected.

15. The method according to claim 14, further comprising configuring the integrated circuit so that it performs, in response to a warning signal, at least one of the following protective actions:
(i) stopping an operation being carried out,
(ii) resetting the integrated circuit,
(iii) erasing all or part of a memory,
(iv) self-destructing the integrated circuit or parts thereof.

16. The method according to claim 10, further comprising arranging the protection capacitors to cover more than 90% of the area occupied by the at least one array of the protection capacitors.

17. The method according to claim 10, further comprising:
providing a third interconnection conductive line arranged above the protection capacitors, and
monitoring the electrical continuity of the third interconnection conductive line and supplying a warning signal to the integrated circuit when a continuity default is detected.
